(19) United States
(12) Patent Application Publication
(10) Pub. No.: US 2024/0076181 A1
(43) Pub. Date: Mar. 7, 2024

(54) MICRO ELECTRO-MECHANICAL SYSTEMS PACKAGE AND MANUFACTURING METHOD

(71) Applicant: SAMSUNG ELECTRO-MECHANICS CO., LTD, Suwon-si (KR)

(72) Inventors: Seung Wook PARK, Suwon-si (KR); Jang Ho PARK, Suwon-si (KR)

(73) Assignee: SAMSUNG ELECTRO-MECHANICS CO., LTD., Suwon-si (KR)

(21) Appl. No.: 18/340,408

(22) Filed: Jun. 23, 2023

(30) Foreign Application Priority Data
Sep. 7, 2022 (KR) 10-2022-0113614

(51) Int. Cl. B81B 7/00; B81C 1/00; H03H 9/10

(52) U.S. Cl. CPC B81B 7/0077; B81C 1/00333; H03H 9/105; B81B 2207/096; B81C 2203/019

(57) ABSTRACT

A micro electro-mechanical systems (MEMS) package includes a first substrate on which at least one connection pad is disposed; a second substrate disposed adjacent to the first substrate; an element unit disposed on one surface of the second substrate; a connecting member connected to the connection pad and a metal pad included in the element unit; a sealing layer which encloses the second substrate; an insulating layer which covers the sealing layer; a redistribution layer connected to the connection pad; and an external connection terminal connected to the redistribution layer and exposed externally from the insulating layer. The element unit is spaced apart from the first substrate, the external connection terminal is exposed externally from the insulating layer disposed on a surface of the package that is opposite to a surface thereof on which the first substrate is disposed.

### CROSS-REFERENCE TO RELATED APPLICATIONS

This application claims the benefit under 35 USC § 119(a) of Korean Patent Application No. 10-2022-0113614, filed on Sep. 7, 2022, in the Korean Intellectual Property Office, the entire disclosure of which is incorporated herein by reference for all purposes.

### BACKGROUND

### 1. Field

The following description relates to a micro electro-mechanical systems (MEMS) package and a MEMS package manufacturing method.

### 2. Description of Related Art

Surface acoustic wave (SAVV) filters and bulk acoustic wave (BAVV) filters, which are band pass filters, are rapidly growing in accordance with a growing communication market. Accordingly, various packaging methods for manufacturing radio frequency (RF) filters, and a thin film package among these packages may implement technology which may occupy technological superiority in a competitively growing micro electro-mechanical systems (MEMS) market.

A polymer used in the thin film package is a photo-definable material, and may be easily processed to have a structure. However, the polymer may have a structural weakness because of its low modulus and high coefficient of thermal expansion (CTE). Accordingly, when having a smaller thickness, the package may have a cavity that collapses during a molding process or may have a structural weakness due to a difference in the coefficient of thermal expansion or the like caused by thermal stress occurring during the molding process.

### SUMMARY

This Summary is provided to introduce a selection of concepts in a simplified form that is further described below in the Detailed Description. This Summary is not intended to identify key features or essential features of the claimed subject matter, nor is it intended to be used as an aid in determining the scope of the claimed subject matter.

In a general aspect, a micro electro-mechanical systems (MEMS) package includes a first substrate having a first surface on which at least one connection pad is disposed; a second substrate disposed adjacent to the first surface of the first substrate; an element unit disposed on a first surface of the second substrate; a connecting member connected to the connection pad and a metal pad comprised in the element unit; a sealing layer disposed on the first surface of the first substrate, and configured to enclose the second substrate; an insulating layer configured to cover the sealing layer; a redistribution layer, connected to the connection pad, and disposed along an interface between the sealing layer and the insulating layer; and an external connection terminal, connected to the redistribution layer, and configured to be exposed externally from the insulating layer, wherein the element unit is spaced apart from the first substrate, and a space is disposed between the element unit and the first substrate, wherein the connecting member is implemented as a boundary between the sealing layer and the space between the element unit and the first substrate, and wherein the external connection terminal is exposed externally from the insulating layer disposed on a surface of the package that is opposite to a surface of the package on which the first substrate is disposed.

The redistribution layer may be connected to one surface of the external connection terminal, and is configured to extend along the interface between the sealing layer and the insulating layer to connect with the connection pad.

The redistribution layer may be configured to extend along a side incline of the sealing layer.

The sealing layer may include a photo-definable polymer material, and the insulating layer comprises a photo-definable material which has a higher strength than a strength of the sealing layer.

The connecting member may be a solder ball that connects the metal pad and the connection pad with each other.

The element unit may be a bulk-acoustic wave (BAVV) resonator.

The redistribution layer may be configured to connect the connecting member and the external connection terminal to each other by a through-via that passes through the sealing layer.

The package may include a passive element disposed on a second surface of the first substrate, and configured to connect to the connection pad.

The passive element may be at least one of an inductor and a capacitor.

The external connection terminal may be a pillar that protrudes from the insulating layer.

The first substrate may be mounted on the second substrate on a same surface of the second substrate on which the element unit is disposed.

In a general aspect, a micro electro-mechanical systems (MEMS) package manufacturing method includes positioning a connection pad on a first surface of a first substrate; mounting a second substrate, which has a first surface on which an element unit is disposed, on the connection pad via a connecting member; laminating a sealing layer to enclose the second substrate, and dispose a space between the first substrate and the element unit; exposing the connection pad by removing a portion of the sealing layer; connecting a redistribution layer to the connection pad; and positioning an insulating layer to cover the sealing layer, and externally expose a portion of the redistribution layer.

The method may further include positioning an external connection terminal to connect the external connection terminal to the exposed portion of the redistribution layer.

The method may further include attaching a support member to a second surface of the first substrate before mounting the second substrate on the connection pad.

The second substrate may include a plurality of second substrates, and a dicing operation is performed between the plurality of second substrates.

The method may further include removing the support member before the dicing operation between the plurality of second substrates.

Other features and aspects will be apparent from the following detailed description, the drawings, and the claims.

### BRIEF DESCRIPTION OF DRAWINGS

FIG. 1 is a schematic cross-sectional view illustrating an example micro electro-mechanical systems (MEMS) package, in accordance with one or more embodiments.

FIGS. 2 through 9 are illustrative process diagrams respectively illustrating an example MEMS package manufacturing method, in accordance with one or more embodiments.

FIG. 10 is a schematic cross-sectional view illustrating an example MEMS package, in accordance with one or more embodiments.

FIG. 11 is a schematic cross-sectional view illustrating an example MEMS package, in accordance with one or more embodiments.

FIG. 12 is a schematic cross-sectional view illustrating an example MEMS package, in accordance with one or more embodiments.

FIG. 13 is a schematic cross-sectional view illustrating an example MEMS package, in accordance with one or more embodiments.

FIG. 14 is a schematic cross-sectional view illustrating an example MEMS package, in accordance with one or more embodiments.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when a component or element is described as being “on”, “connected to,” “coupled to,” or “joined to” another component, element, or layer it may be directly (e.g., in contact with the other component or element) “on”, “connected to,” “coupled to,” or “joined to” the other component, element, or layer or there may reasonably be one or more other components, elements, layers intervening therebetween. When a component or element is described as being “directly on”, “directly connected to,” “directly coupled to,” or “directly joined” to another component or element, there can be no other elements intervening therebetween. Likewise, expressions, for example, “between” and “immediately between” and “adjacent to” and “immediately adjacent to” may also be construed as described in the foregoing.

As used herein, the term “and/or” includes any one and any combination of any two or more of the associated listed items. The phrases “at least one of A, B, and C”, “at least one of A, B, or C’, and the like are intended to have disjunctive meanings, and these phrases “at least one of A, B, and C”, “at least one of A, B, or C’, and the like also include examples where there may be one or more of each of A, B, and/or C (e.g., any combination of one or more of each of A, B, and C), unless the corresponding description and embodiment necessitates such listings (e.g., “at least one of A, B, and C”) to be interpreted to have a conjunctive meaning.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

One or more examples may provide a micro electro-mechanical systems (MEMS) package which may overcome structural weakness, and may improve a manufacturing yield thereof, and a method for manufacturing the same.

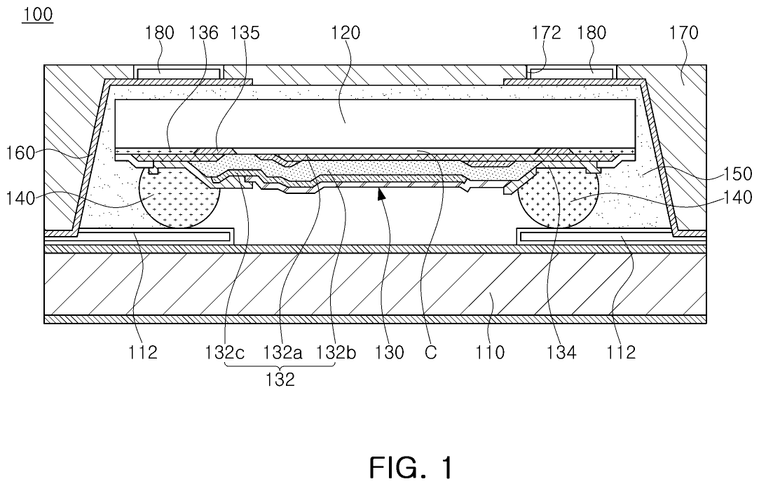

FIG. 1 is a schematic cross-sectional view illustrating an example micro electro-mechanical systems (MEMS) package, in accordance with one or more embodiments.

Referring to FIG. 1, an example MEMS package 100 may include, for example, a first substrate 110, a second substrate 120, an element unit 130, a connecting member 140, a sealing layer 150, a redistribution layer 160, an insulating layer 170, and an external connection terminal 180.

In a non-limiting example, the first substrate 110 may be a silicon substrate. In a non-limiting example, the second substrate 120 may be a silicon wafer, a silicon on insulator (SOI) type substrate, or a glass core substrate, as only examples. In an example, the first substrate 110 may include a connection pad 112 that is electrically connected to the external connection terminal 180 and the connecting member 140. In an example, the connection pad 112 may be one connection pad 112 or a plurality of connection pads 112. In an example, the plurality of connection pads 112 may be disposed on an upper surface of the first substrate 110 while being spaced apart from each other. FIG. 1 illustrates an example in which two connection pads 112 are spaced apart from each other. However, the number of connection pads 112 is not limited thereto.

The second substrate 120 may be disposed adjacent to a first surface of the first substrate 110. In an example, the second substrate 120 may be spaced apart from the first substrate 110 by a predetermined distance, and the element unit 130 may be disposed on a first surface of the second substrate 120. In an example, the second substrate 120 may be buried in the sealing layer 150. In an example, the second substrate 120 may be a silicon wafer or a silicon on insulator (501) type substrate.

The element unit 130 may be disposed on one surface of the second substrate 120. In an example, the element unit 130 may be a bulk-acoustic wave (BAW) resonator. However, the element unit 130 is not limited thereto, and the element unit 130 may be a surface-acoustic wave (SAW) resonator or a MEMS device. In an example, the element unit 130 may include a resonator 132 that is spaced apart from the second substrate 120. A cavity C may be formed between the resonator 132 and the second substrate 120. The resonator 132 may include a first electrode 132a, a piezoelectric layer 132b, and a second electrode 132c. Additionally, the element unit 130 may include a metal pad 134 to which the connecting member 140 is connected. The metal pad 134 may be connected to the first electrode 132a and the second electrode 132c of the resonator 132. Additionally, the element unit 130 may include an etch resist portion 135 that surrounds the cavity C, and a sacrificial layer 136 disposed outside the etch resist portion 135.

The connecting member 140 may be disposed between the connection pad 112 of the first substrate 110 and the metal pad 134 of the element unit 130. In an example, the connecting member 140 may be a solder ball including a material such as, but not limited to, lead or copper. The connecting member 140 may mount the second substrate 120 and the element unit 130, which may be manufactured as one electronic part, on the first substrate 110. Additionally, the connecting member 140 may be implemented to supply power to the element unit 130 when the power is supplied from an external source. The connecting member 140 may also be implemented as a boundary between the sealing layer 150 and a space between the element unit 130 and the first substrate 110. In other words, the sealing layer 150 may be disposed outside the connecting member 140 with the connecting member 140 as the boundary.

The sealing layer 150 may bury the second substrate 120. In an example, the sealing layer 150 may be disposed outside the connecting member 140, and a space may be created between the first substrate 110 and the element unit 130 based on the disposition of the sealing layer outside of the connecting member 140. The sealing layer 150 may bury or enclose the second substrate 120. In an example, the sealing layer 150 may include a photo-definable polymer material. In an example, a side surface of the sealing layer 150 may be disposed at an incline. The reason why the side surface of the sealing layer 150 is inclined is that a via may be formed in the sealing layer 150 in a photo-lithography process.

The redistribution layer 160 may connect the connection pad 112 of the first substrate 110 and the external connection terminal 180 with each other. In an example, the redistribution layer 160 may be disposed between the insulating layer 170 and the sealing layer 150, between the insulating layer 170 and the connection pad 112, and between the external connection terminal 180 and the sealing layer 150. In other words, the redistribution layer 160 may be connected to one surface of the external connection terminal 180 and may extend along an interface between the sealing layer 150 and the insulating layer 170 to be connected to the connection pad 112. In an example, the redistribution layer 160 may electrically connect the connecting member 140 and the external connection terminal 180 to each other via or through the connection pad 112 of the first substrate 110. In an example, the redistribution layer 160 may extend along the side incline of the sealing layer 150.

The insulating layer 170 may cover the sealing layer 150. In an example, the insulating layer 170 may include a photo-definable material, and may not be deformed or damaged by an external environment. In an example, the insulating layer 170 may include the photo-definable material which has higher strength than a strength of the sealing layer 150. In an example, the insulating layer 170 may protect the sealing layer 150, the second substrate 120, and the element unit 130 which are respectively arranged inwardly of the external environment. In an example, the insulating layer 170 may include an insertion groove 172 into which the external connection terminal 180 may be inserted.

The external connection terminal 180 may be inserted into the insertion groove 172 of the insulating layer 170, and may thus be externally exposed. In an example, the external connection terminal 180 may supply power to the element unit 130 based on a connection to an external power source.

As described above, the insulating layer 170 may be provided with the external connection terminal 180 to which the power is supplied from an external power source through the redistribution layer 160, and accordingly, the first substrate 110 may not need a wiring layer or the like. It is thus possible to improve manufacturing yield of the product.

Additionally, the second substrate 110 and the element unit 130 may be sealed by the sealing layer 150 and the insulating layer 170, thereby compensating for collapse of the space between the first substrate 110 and the element unit 130 due to the external environment or structural weakness of the package, caused by a difference in a coefficient of thermal expansion.

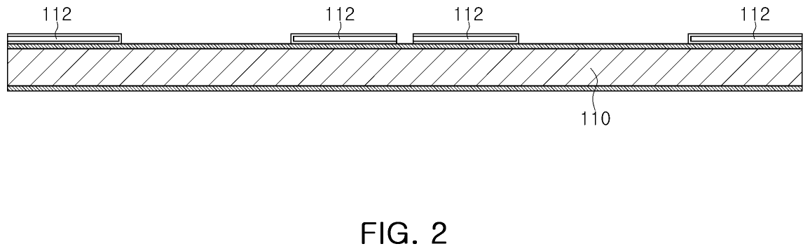

FIGS. 2 through 9 are illustrative process diagrams respectively illustrating a MEMS package manufacturing method, in accordance with one or more embodiments.

First, as illustrated in FIG. 2, a plurality of connection pads 112 may be disposed on one surface of a first substrate 110.

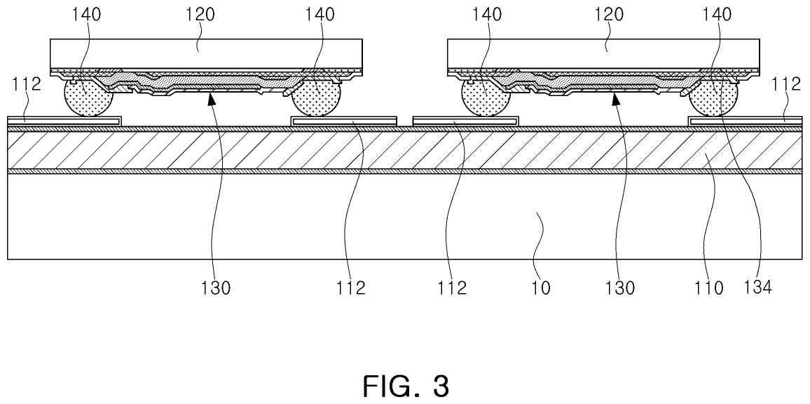

Next, as illustrated in FIG. 3, the first substrate 110 may be mounted with a second substrate 120 and an element unit 130 which may be manufactured as one electronic part by positioning the element unit 130 on one surface of the second substrate 120, via a connecting member 140. In an example, the connecting member 140 may be disposed in advance on the second substrate 120 and the element unit 130 which may be manufactured as one electronic part. In an example, the connecting member 140 may be disposed on a metal pad 134 of the element unit 130. Next, the first substrate 110 may be mounted with the second substrate 120 and the element unit 130 which may be manufactured as one electronic part by positioning the element unit 130 on one surface of the second substrate 120 by flip bonding through the connecting member 140. In an example, as illustrated in FIG. 3, a support member 10, that prevents deformation of the first substrate 110, may be attached to the other (or a second) surface of the first substrate 110.

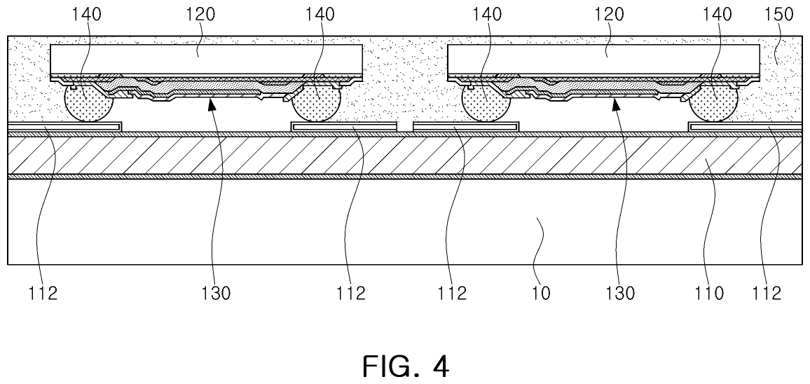

Next, as illustrated in FIG. 4, a sealing layer 150 may be formed. The sealing layer 150 may cover the second substrate 120 manufactured as one electronic part. A space may be formed inside the connecting member 140, and specifically, between the connecting member 140 and the second substrate 120. The sealing layer 150 may include a photo-definable material and be made by laminating dry films.

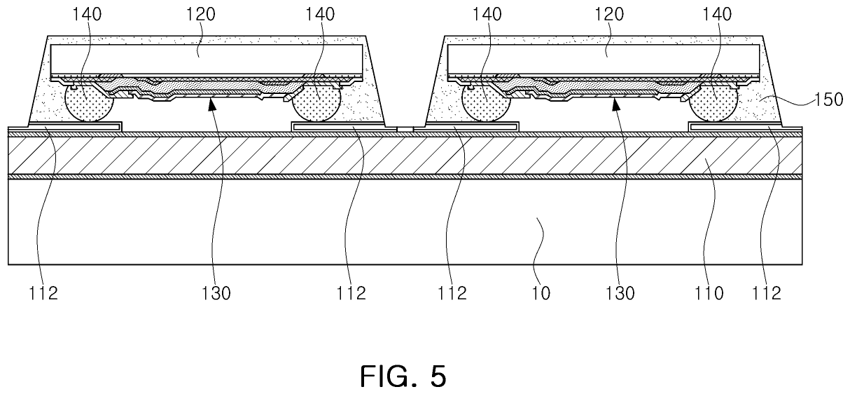

Next, as illustrated in FIG. 5, a portion of the sealing layer 150 may be removed using, as an example, a photo lithography process.

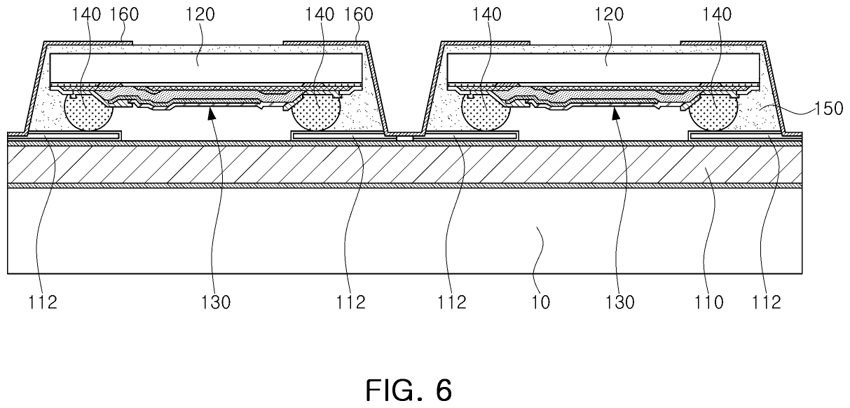

Next, as illustrated in FIG. 6, a redistribution layer 160 may be disposed in a region from which the sealing layer 150 is removed. The redistribution layer 160 may be made using a method such as, but not limited to, plating or sputtering.

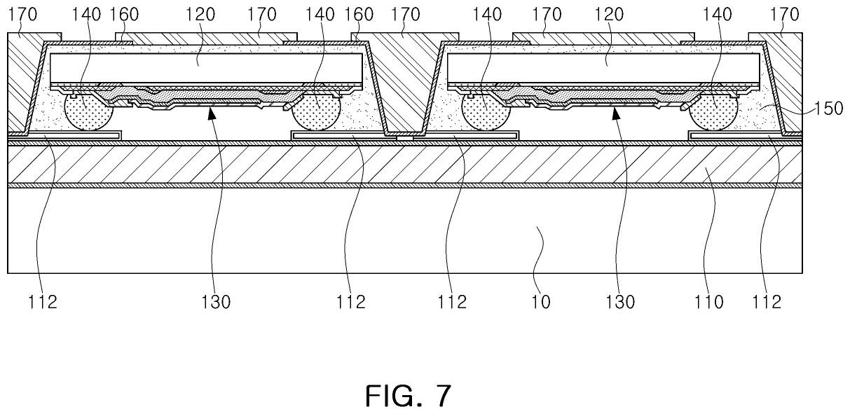

Next, as illustrated in FIG. 7, an insulating layer 170 may be disposed to expose only a portion of the redistribution layer 160 disposed on one surface of the sealing layer 150. Meanwhile, the insulating layer 170 may include the photo-definable material, and may not be deformed or damaged by an external environment. In an example, the insulating layer 170 may be made using a method such as, but not limited to, lamination or screen printing by using a photo-definable film. In an example, a portion of the redistribution layer 160 may be exposed from the insulating layer 170 by using an exposure method, a development method, or the like.

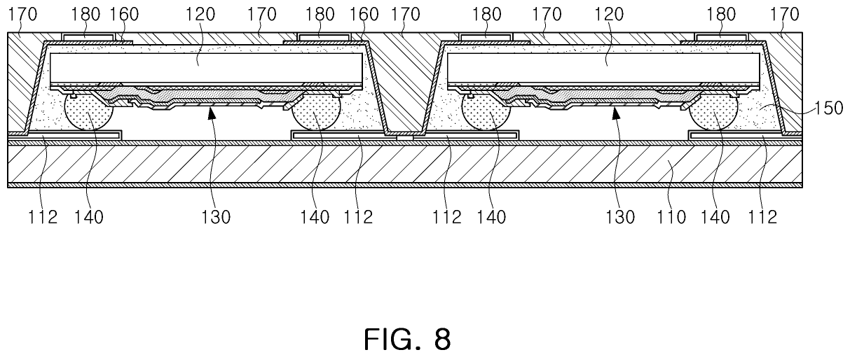

Next, as illustrated in FIG. 8, an external connection terminal 180 may be disposed on the redistribution layer 160. Next, the support member 10 may be removed from the first substrate 110.

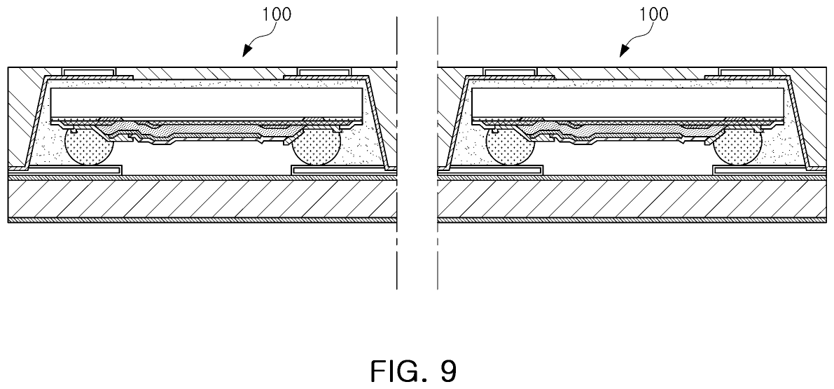

Next, a MEMS package 100 may be completed as illustrated in FIG. 9 by dicing between the plurality of second substrates to satisfy a standard thereof.

As described above, the first substrate 110 may be mounted with the element unit 130, the second substrate 120, and the connecting member 140 manufactured as one electronic part by the flip bonding, thereby improving the manufacturing yield.

Additionally, the element unit 130, the second substrate 120, and the connecting member 140, which may be manufactured as one electronic part, may be manufactured as multi-chips rather than a single chip. In this example, it is possible to make an overall size of the MEMS package 100 smaller by reducing a gap between the multi-chips.

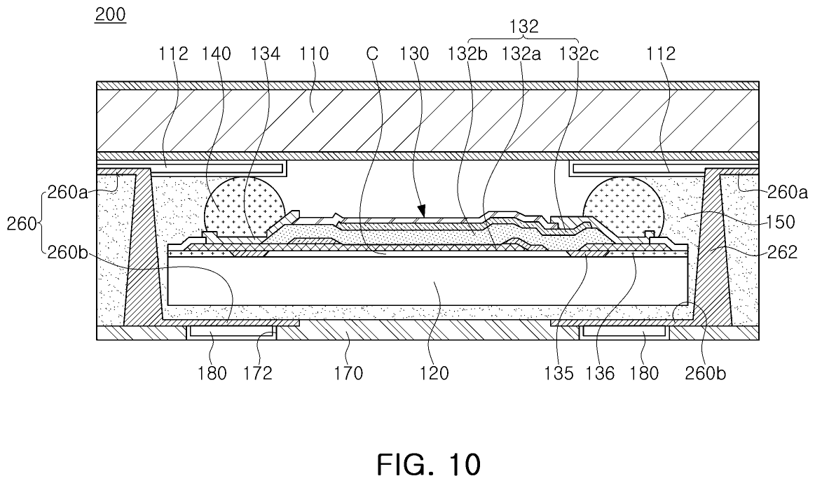

FIG. 10 is a schematic cross-sectional view illustrating a MEMS package, in accordance with one or more embodiments.

Referring to FIG. 10, an example MEMS package 200, in accordance with one or more embodiments, may include, for example, the first substrate 110, the second substrate 120, the element unit 130, the connecting member 140, the sealing layer 150, a redistribution layer 260, the insulating layer 170, and the external connection terminal 180.

In an example, the first substrate 110, the second substrate 120, the element unit 130, the connecting member 140, the sealing layer 150, the insulating layer 170, and the external connection terminal 180 are substantially the same as the components described above. Detailed descriptions thereof are thus omitted here and replaced by the above descriptions.

The redistribution layer 260 may include a first redistribution layer 260a connected to the connection pad 112 of the substrate 110 and a second redistribution layer 260b connected to the external connection terminal 180. In an example, the first redistribution layer 260a and the second redistribution layer 260b may be connected to each other through a through-via 262. In an example, the redistribution layer 260 may electrically connect the external connection terminal 180 and the element unit 130 with each other via or through the connecting member 140, so that the power is supplied to the element unit 130.

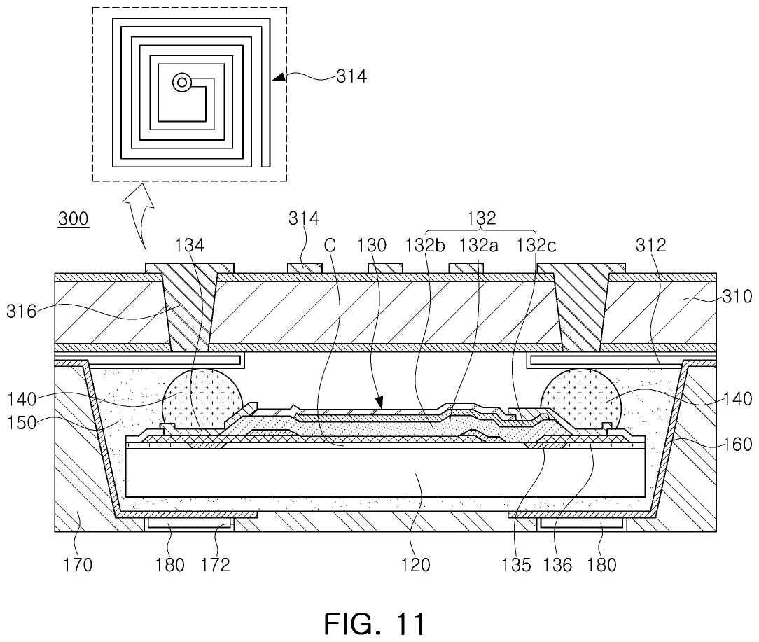

FIG. 11 is a schematic cross-sectional view showing an example MEMS package, in accordance with one or more embodiments.

Referring to FIG. 11, an example MEMS package 300, in accordance with one or more embodiments, may include, for example, a first substrate 310, the second substrate 120, the element unit 130, the connecting member 140, the sealing layer 150, the redistribution layer 160, the insulating layer 170, and the external connection terminal 180.

In an example, the second substrate 120, the element unit 130, the connecting member 140, the sealing layer 150, the redistribution layer 160, the insulating layer 170, and the external connection terminal 180 are substantially the same as the components described above. Detailed descriptions thereof are thus omitted here and replaced by the above descriptions.

In an example, the first substrate 310 may be the silicon substrate. For example, the substrate 120 may be a silicon wafer, a silicon on insulator (SOI) type substrate, or a glass core substrate. In an example, the first substrate 310 may include a connection pad 312 electrically connected to the external connection terminal 180 and the connecting member 140. In an example, the plurality of connection pads 312 may be disposed on one surface of the first substrate 310 while being spaced apart from each other. In an example, FIG. 11 illustrates an example in which two connection pads 312 are spaced apart from each other. However, the number of connection pads 312 is not limited thereto.

In an example, a passive element 314 may be disposed on the other surface of the first substrate 310. The passive element 314 may be, as non-limiting examples, an inductor or/and a capacitor. Additionally, the passive element 314 may be connected to the connection pad 312 by a connection via 316 of the first substrate 310.

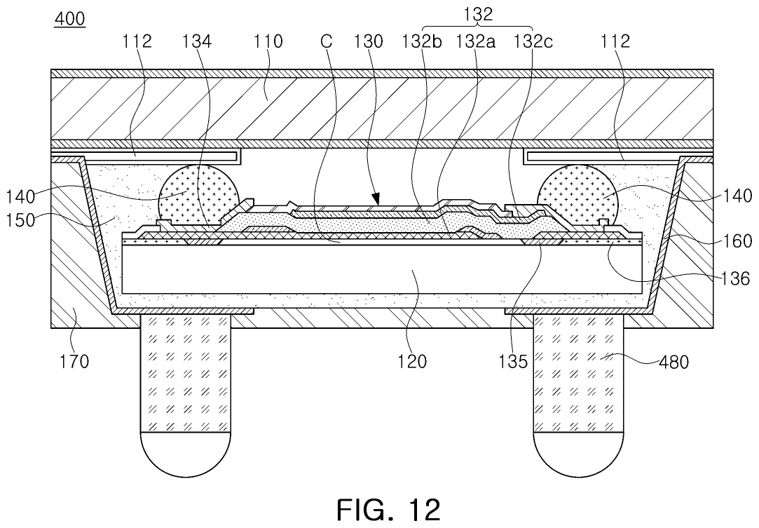

FIG. 12 is a schematic cross-sectional view illustrating an example MEMS package, in accordance with one or more embodiments.

Referring to FIG. 12, an example MEMS package 400, in accordance with one or more embodiments, may include, for example, the first substrate 110, the second substrate 120, the element unit 130, the connecting member 140, the sealing layer 150, the redistribution layer 160, the insulating layer 170, and an external connection terminal 480.

In an example, the first substrate 110, the second substrate 120, the element unit 130, the connecting member 140, the sealing layer 150, the redistribution layer 160, and the insulating layer 170 are substantially the same as the components described above. Detailed descriptions thereof are thus omitted here and replaced by the above descriptions.

The external connection terminal 480 may be connected to the redistribution layer 160, and may protrude from the insulating layer 170. In an example, the external connection terminal 480 may include a copper material, and may be a pillar having a cylindrical shape, as only an example. However, the external connection terminal 480 is not limited thereto, and may be any one of a solder ball and a land grid array (LGA). In an example, the external connection terminal 480 may supply power to the element unit 130 by being connected to the external power source.

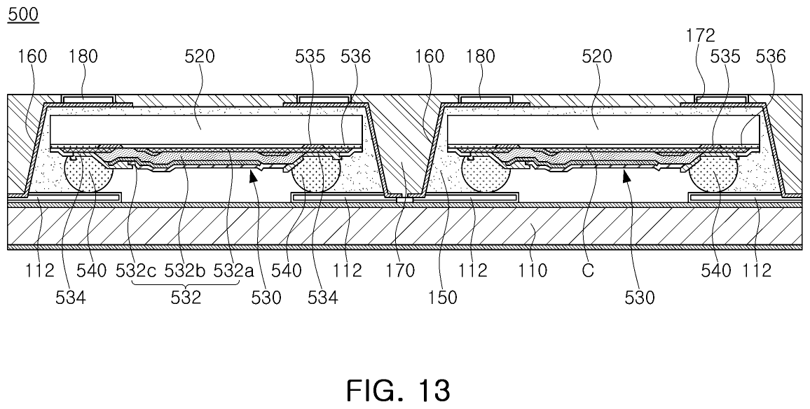

FIG. 13 is a schematic cross-sectional view illustrating an example MEMS package, in accordance with one or more embodiments.

Referring to FIG. 13, an example MEMS package 500, in accordance with one or more embodiments, may include, for example, the first substrate 110, a second substrate 520, an element unit 530, a connecting member 540, the sealing layer 150, the redistribution layer 160, the insulating layer 170, and the external connection terminal 180.

In an example, the first substrate 110, the sealing layer 150, the redistribution layer 160, the insulating layer 170, and the external connection terminal 180 are substantially the same as the components described above. Detailed descriptions thereof are thus omitted here and replaced by the above descriptions.

The second substrate 520 may be spaced apart from the first substrate 110 by a predetermined distance, and the element unit 530 may be disposed on one surface of the second substrate 520. In an example, the second substrate 520 may be buried in the sealing layer 150. In an example, the second substrate 520 may be a silicon wafer or a silicon on insulator (501) type substrate.

The element unit 530 may be disposed on one surface of the second substrate 520. For example, the element unit 530 may be a bulk-acoustic wave (BAW) resonator. However, the element unit 530 is not limited thereto, and may be a surface-acoustic wave (SAW) resonator or the MEMS device. In an example, the element unit 530 may include a resonator 532 that is spaced apart from the second substrate 520. A cavity C may be formed between the second substrate 520 and the element unit 530. The resonator 532 may include a first electrode 532a, a piezoelectric layer 532b, and a second electrode 532c. Additionally, the element unit 530 may include a metal pad 534 to which the connecting member 540 is connected. In an example, the metal pad 534 may be connected to the first and second electrodes 532a and 532c of the resonator 532. Additionally, the element unit 530 may include an etch resist portion 535 that surrounds the cavity C, and a sacrificial layer 536 that is disposed outside the etch resist portion 535.

The connecting member 540 may be disposed between the connection pad 112 of the first substrate 110 and the metal pad 534 of the element unit 530. In a non-limited example, the connecting member 540 may be a solder ball including a material such as, but not limited to, lead or copper. In an example, the connecting member 540 may mount the second substrate 520 and the element unit 530 manufactured as one electronic part on the first substrate 110. Additionally, the connecting member 540 may supply the power to the element unit 530 when the power is supplied from an external source.

In an example, the second substrate 520, the element unit 530, and the connecting member 540 may be manufactured as one electronic part and then mounted on the first substrate 110. FIG. 13 illustrates an example in which the first substrate 110 is mounted with two multi-chips in each of which the second substrate 520, the element unit 530, and the connecting member 540 may be manufactured as one electronic part. However, the multi-chips are not limited to this number and the first substrate 110 may be mounted with three or more multi-chips each of which may be manufactured as one electronic part.

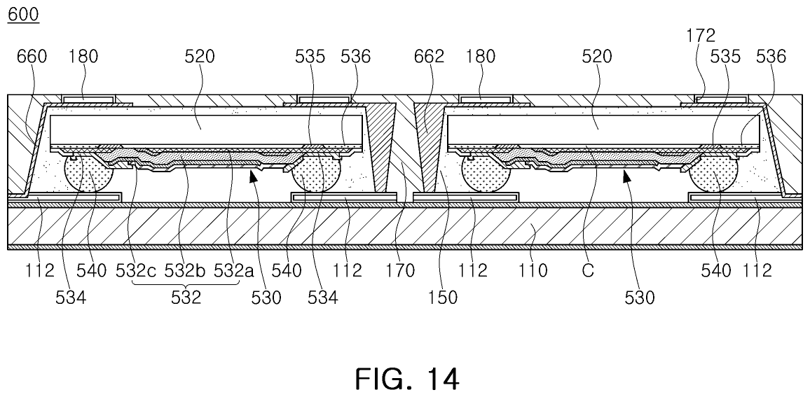

FIG. 14 is a schematic cross-sectional view illustrating an example MEMS package, in accordance with one or more embodiments.

Referring to FIG. 14, an example MEMS package 600, in accordance with one or more embodiments, may include, for example, the first substrate 110, the second substrate 520, the element unit 530, the connecting member 540, the sealing layer 150, a redistribution layer 660, the insulating layer 170, and the external connection terminal 180.

In an example, the first substrate 110, the sealing layer 150, the insulating layer 170, and the external connection terminal 180 are substantially the same as the components described above. Detailed descriptions thereof are thus omitted here and replaced by the above descriptions.

Additionally, the second substrate 520, the element unit 530, and the connecting member 540 are substantially the same as the components described in the descriptions provided with reference to FIG. 13. Detailed descriptions thereof are thus omitted here and replaced by the above descriptions.

The redistribution layer 660 may be in contact with the connection pad 112 of the first substrate 110 and the external connection terminal 180. In an example, some of the plurality of connection pads 112 and some of the external connection terminals 180 may respectively be connected to each other by the redistribution layer 660, and the redistribution layer 660 in contact with the external connection terminal 180 may be connected to the connection pad 112 by the through-via 262. In other words, the connection pad 112 of the first substrate 110 and the external connection terminal 180 may be connected to each other only by the redistribution layer 660, or connected by the redistribution layer 660 and the through-via 262.

As set forth above, in accordance with one or more embodiments, the example MEMS package may overcome the structural weakness and improve the manufacturing yield.

While this disclosure includes specific examples, it will be apparent to one of ordinary skill in the art, after an understanding of the disclosure of this application, that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, the scope of the disclosure is defined not by the detailed description, but by the claims and their equivalents, and all variations within the scope of the claims and their equivalents are to be construed as being included in the disclosure.

What is claimed is:

1. A micro electro-mechanical systems (MEMS) package, comprising:
a first substrate having a first surface on which at least one connection pad is disposed;
a second substrate disposed adjacent to the first surface of the first substrate;
an element unit disposed on a first surface of the second substrate;
a connecting member connected to the connection pad and a metal pad comprised in the element unit;
a sealing layer disposed on the first surface of the first substrate, and configured to enclose the second substrate;
an insulating layer configured to cover the sealing layer;
a redistribution layer, connected to the connection pad, and disposed along an interface between the sealing layer and the insulating layer; and
an external connection terminal, connected to the redistribution layer, and configured to be exposed externally from the insulating layer,
wherein the element unit is spaced apart from the first substrate, and a space is disposed between the element unit and the first substrate,
wherein the connecting member is implemented as a boundary between the sealing layer and the space between the element unit and the first substrate, and
wherein the external connection terminal is exposed externally from the insulating layer disposed on a surface of the package that is opposite to a surface of the package on which the first substrate is disposed.

2. The package of claim 1, wherein the redistribution layer is connected to one surface of the external connection terminal, and is configured to extend along the interface between the sealing layer and the insulating layer to connect with the connection pad.

3. The package of claim 2, wherein the redistribution layer is configured to extend along a side incline of the sealing layer.

4. The package of claim 1, wherein the sealing layer comprises a photo-definable polymer material, and the insulating layer comprises a photo-definable material which has a higher strength than a strength of the sealing layer.

5. The package of claim 1, wherein the connecting member is a solder ball that connects the metal pad and the connection pad with each other.

6. The package of claim 1, wherein the element unit is a bulk-acoustic wave (BAW) resonator.

7. The package of claim 1, wherein the redistribution layer is configured to connect the connecting member and the external connection terminal to each other by a through-via that passes through the sealing layer.

8. The package of claim 1, further comprising a passive element disposed on a second surface of the first substrate, and configured to connect to the connection pad.

9. The package of claim 8, wherein the passive element is at least one of an inductor and a capacitor.

10. The package of claim 1, wherein the external connection terminal is a pillar that protrudes from the insulating layer.

11. The package of claim 1, wherein the first substrate is mounted on the second substrate on a same surface of the second substrate on which the element unit is disposed.

12. A micro electro-mechanical systems (MEMS) package manufacturing method, the method comprising:
positioning a connection pad on a first surface of a first substrate;
mounting a second substrate, which has a first surface on which an element unit is disposed, on the connection pad via a connecting member;
laminating a sealing layer to enclose the second substrate, and dispose a space between the first substrate and the element unit;
exposing the connection pad by removing a portion of the sealing layer;
connecting a redistribution layer to the connection pad; and
positioning an insulating layer to cover the sealing layer, and externally expose a portion of the redistribution layer.

13. The method of claim 12, further comprising:
positioning an external connection terminal to connect the external connection terminal to the exposed portion of the redistribution layer.

14. The method of claim 13, further comprising attaching a support member to a second surface of the first substrate before mounting the second substrate on the connection pad.

15. The method of claim 13, wherein the second substrate comprises a plurality of second substrates, and
a dicing operation is performed between the plurality of second substrates.

16. The method of claim 15, further comprising removing the support member before the dicing operation between the plurality of second substrates.
